(19) United States
(12) Patent Application Publication
(10) Pub. No.: US 2024/0395517 A1
(43) Pub. Date: Nov. 28, 2024

(54) DATA CALCULATION METHOD AND SUBSTRATE PROCESSING DEVICE

(71) Applicant: Tokyo Electron Limited, Tokyo (JP)

(72) Inventor: Yohei YAMAZAWA, Miyagi (JP)

(73) Assignee: Tokyo Electron Limited, Tokyo (JP)

(21) Appl. No.: 18/792,901

(22) Filed: Aug. 2, 2024

Related U.S. Application Data
(63) Continuation of application No. PCT/JP2023/002385, filed on Jan. 26, 2023.

(30) Foreign Application Priority Data
Feb. 3, 2022 (JP) 2022-015342

(51) Int. Cl. H01J 37/32

(52) U.S. Cl. CPC H01J 37/32926; H01J 37/32935

(57) ABSTRACT

A data calculation method includes: acquiring a first data group for a predetermined period; dividing the first data group into a plurality of groups according to a range of each data value included in the first data group; extracting a second data group included in a valid group among the plurality of groups; and outputting a statistical value for each of the plurality of groups based on the second data group.

### CROSS-REFERENCE TO RELATED APPLICATIONS

This application is a Continuation of International Patent Application No. PCT/JP2023/002385, filed on Jan. 26, 2023, which claims priority from Japanese Patent Application No. 2022-015342, filed on Feb. 3, 2022, with the Japan Patent Office, all of which are incorporated herein in their entireties by reference.

### TECHNICAL FIELD

The present disclosure relates to a data calculation method and a substrate processing apparatus.

### BACKGROUND

In a plasma processing apparatus, for example, a radio frequency (RF) voltage is supplied to a processing target substrate generating plasma, so that ions or radicals generated by the plasma are attracted to the substrate, and a process such as an etching is performed. The voltage Vpp on the substrate is monitored and recorded as an index of a process state, and is used for predicting a process result, status monitoring, and abnormality detection. Also, conducting a feedback control has been suggested, by monitoring the peak voltage value of a pulsed RF bias voltage (see, e.g., Japanese Patent Laid-Open Publication No. 2010-504614).

### SUMMARY

A data calculation method according to an aspect of the present disclosure includes: acquiring a first data group for a predetermined period; dividing the first data group into a plurality of groups according to a range of each data value included in the first data group; extracting a second data group included in a valid group among the plurality of groups; and outputting a statistical value for each of the plurality of groups base on the second data group.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view illustrating an example of a plasma processing apparatus according to an embodiment of the present disclosure.

FIG. 2 is a block diagram illustrating an example of the functional configuration of a controller according to an embodiment.

FIG. 3 is a view illustrating an example of a waveform of a bias voltage when a plurality of RF signals is supplied.

FIG. 4 is a view illustrating the outline of group division according to an embodiment.

FIG. 5 is a view illustrating an example of group division in the present embodiment.

FIG. 6 is a view illustrating an example of a case where group division is performed by using the average value according to an embodiment.

FIG. 7 is a view illustrating an example of valid group extraction according to an embodiment.

FIG. 8 is a view illustrating an example of the level value of each level calculated according to an embodiment.

FIG. 9 is a flowchart illustrating an example of data calculation processing according to an embodiment.

FIG. 10 is a flowchart illustrating an example of extraction processing according to an embodiment.

FIG. 11 is a view illustrating an example of the one-dimensional cluster analysis result, in Example 1 according to an embodiment.

FIG. 12 is a view illustrating an example of the result when the one-dimensional cluster analysis of Example 1 is repeated a predetermined number of times;

FIG. 13 is a view illustrating an example of the ratio of the number of data points for each level value in Example 1.

FIG. 14 is a view illustrating an example of the relationship between the data set and group division in Example 2.

FIG. 15 is a view illustrating an example of the relationship between the data set and group division in Example 3.

FIG. 16 is a view illustrating an example of the level value of each level calculated in Example 3.

### DETAILED DESCRIPTION

In the following detailed description, reference is made to the accompanying drawings which form a part hereof. The illustrative embodiments described in the detailed description, drawings, and claims are not meant to be limiting. Other embodiments may be utilized, and other changes may be made without departing from the spirit or scope of the subject matter presented herein.

Hereinafter, embodiments of the disclosed data calculation method and substrate processing apparatus will be described in detail on the basis of drawings. The disclosed technology is not limited by the following embodiments.

In recent years, in a plasma processing apparatus, there is a case where a fine process control is performed by supplying an RF signal as a pulse that is turned On/Off at high speeds. When the RF signal is supplied as a pulse, since the voltage Vpp on the monitoring target substrate is also in a pulsed state, it is necessary to monitor the voltage Vpp in the pulsed state. However, in monitoring the peak voltage value of the pulsed RF bias voltage, it is difficult to monitor a level value of each voltage level, regarding the pulse waveform having a plurality of levels, such as RF signals having different frequencies supplied in a superimposed manner.

Also, in another method, the level value of a level may be detected based on the timing of the pulse of the bias RF signal, but it is difficult to detect the level value of a level if the output of a source RF signal changes. Furthermore, the method of differentiating the pulse waveform and extracting the inflection point from the pulse waveform is easily affected by noise, and requires a separate system for performing level extraction, and thus, is difficult to use in the control of the plasma processing apparatus. Also, a general cluster analysis is difficult to use in the control of the plasma processing apparatus because classification in multiple dimensions is targeted, and the amount of calculation is large. Therefore, it is expected to obtain the level value and ratio of each level in the pulse waveform having a plurality of levels.

### [Configuration of Plasma Processing Apparatus]

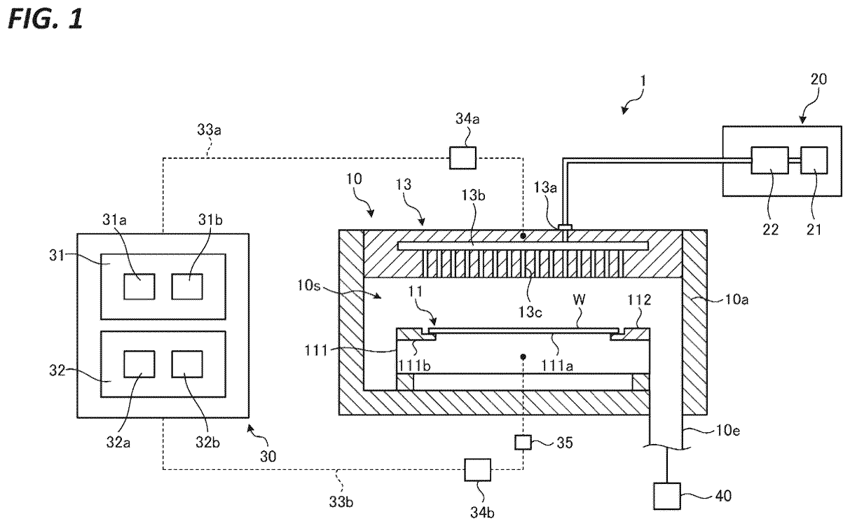

Hereinafter, descriptions will be made on a configuration example of a capacitively coupled plasma processing apparatus which serves as an example of a plasma processing apparatus 1. FIG. 1 is a view illustrating an example of a plasma processing apparatus in one embodiment of the present disclosure. As illustrated in FIG. 1, the capacitively coupled plasma processing apparatus 1 includes a plasma processing chamber 10, a gas supply 20, a power supply 30, and an exhaust system 40. Also, the plasma processing apparatus 1 includes a substrate support 11 and a gas introduction section. The gas introduction section is configured to introduce at least one processing gas into the plasma processing chamber 10. The gas introduction section includes a shower head 13. The substrate support 11 is disposed within the plasma processing chamber 10. The shower head 13 is disposed above the substrate support 11. In one embodiment, the shower head 13 constitutes at least a part of the ceiling of the plasma processing chamber 10. The plasma processing chamber 10 has a plasma processing space 10s defined by the shower head 13, a side wall 10a of the plasma processing chamber 10, and the substrate support 11. The side wall 10a is grounded. The shower head 13 and the substrate support 11 are electrically insulated from the housing of the plasma processing chamber 10.

The substrate support 11 includes a main body 111 and a ring assembly 112. The main body 111 has a central region (substrate supporting surface) 111a for supporting a substrate (wafer) W, and an annular region (ring supporting surface) 111b for supporting the ring assembly 112. In the plan view of FIG. 1, the annular region 111b of the main body 111 surrounds the central region 111a of the main body 111. The substrate W is disposed on the central region 111a of the main body 111, and the ring assembly 112 is disposed on the annular region 111b of the main body 111 so as to surround the substrate W on the central region 111a of the main body 111. In one embodiment, the main body 111 includes a base and an electrostatic chuck. The base includes a conductive member. The conductive member of the base functions as a lower electrode. The electrostatic chuck is disposed on the base. The top surface of the electrostatic chuck has the substrate supporting surface 111a. The ring assembly 112 includes one or more annular members. At least one of one or more annular members is an edge ring. Also, the substrate support 11 may include a temperature control module configured to control at least one of the electrostatic chuck, the ring assembly 112, and the substrate W, to a target temperature, but an illustration thereof is omitted. The temperature control module may include a heater, a heat transfer medium, and a flow path or a combination thereof. A heat transfer fluid such as brine or gas flows through the flow path. Also, the substrate support 11 may include a heat transfer gas supply configured to supply a heat transfer gas to the gap between the back surface of the substrate W and the substrate supporting surface 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a is introduced into the plasma processing space 10s from the plurality of gas introduction ports 13c through the gas diffusion chamber 13b. Also, the shower head 13 includes a conductive member. The conductive member of the shower head 13 functions as an upper electrode. In addition to the shower head 13, the gas introduction section may include one or more side gas injectors (SGIs) attached to one or more openings formed in the side wall 10a.

The gas supply 20 may include at least one gas source 21 and at least one flow controller 22. In one embodiment, the gas supply 20 is configured to supply at least one processing gas to the shower head 13 from each corresponding gas source 21 through each corresponding flow controller 22. Each flow controller 22 may include, for example, a mass flow controller or a pressure control-type flow controller. Furthermore, the gas supply 20 may include at least one flow modulation device that modulates the flow rate of at least one processing gas or produces a pulse.

The power supply 30 includes an RF power supply 31 coupled to the plasma processing chamber 10 via at least one impedance matching circuit. The RF power supply 31 is configured to supply at least one RF signal (RF power) such as a source RF signal and a bias RF signal, to the conductive member of the substrate support 11 and/or the conductive member of the shower head 13. Accordingly, plasma is formed from at least one processing gas supplied to the plasma processing space 10s. Therefore, the RF power supply 31 may function at least as a part of a plasma generator. Also, when a bias RF signal is supplied to the conductive member of the substrate support 11, a bias potential is generated in the substrate W, and ion components in the formed plasma may be attracted to the substrate W.

In one embodiment, the RF power supply 31 includes a first RF generator 31a and a second RF generator 31b. The first RF generator 31a is coupled to the conductive member of the substrate support 11 and/or the conductive member of the shower head 13 via at least one impedance matching circuit, and is configured to generate a source RF signal (source RF power) for plasma generation. In one embodiment, the source RF signal has a frequency within a range of 13 MHz to 150 MHz. In one embodiment, the first RF generator 31a may be configured to generate source RF signals having different frequencies. One or more generated source RF signals are supplied to the conductive member of the substrate support 11 and/or the conductive member of the shower head 13. The second RF generator 31b is coupled to the conductive member of the substrate support 11 via at least one impedance matching circuit, and is configured to generate a bias RF signal (bias RF power). In one embodiment, the bias RF signal has a frequency lower than the source RF signal. In one embodiment, the bias RF signal has a frequency within a range of 400 kHz to 13.56 MHz. In one embodiment, the second RF generator 31b may be configured to generate bias RF signals having different frequencies. One or more generated bias RF signals are supplied to the conductive member of the substrate support 11. Also, in various embodiments, at least one of the source RF signal and the bias RF signal may be pulsed.

For example, the first RF generator 31a is electrically connected to the conductive member of the shower head 13 via a conductive portion 33a such as by wired connections. An impedance matching circuit 34a is provided in the conductive portion 33a. The impedance matching circuit 34a matches the output impedance of the first RF generator 31a with the input impedance on the load side (the shower head 13 side). The first RF generator 31a supplies a source RF signal for generating plasma, to the conductive member of the shower head 13.

Also, for example, the second RF generator 31b is electrically connected to the conductive member of the base of the substrate support 11 via a conductive portion 33b such as wired connections. An impedance matching circuit 34b is provided in the conductive portion 33b. The impedance matching circuit 34b matches the output impedance of the second RF generator 31b with the input impedance on the load side (the substrate support 11 side). The second RF generator 31b supplies a bias RF signal for attracting ion components in plasma to the substrate W, to the conductive member of the substrate support 11.

In the plasma processing apparatus 1, a measuring unit 35 that measures either a voltage or a current is provided on an electrode disposed in the plasma processing chamber 10 or on wired connections, which are connected to the electrode. In the present embodiment, the measuring unit 35 is provided on the conductive portion 33b connected to the conductive member of the substrate support 11. The measuring unit 35 has a configuration where a probe for detecting a current and a voltage is included, and measures the voltage and the current. The measuring unit 35 measures the voltage, and the current of the conductive portion 33b through which the bias RF signal flows, and outputs a signal indicating the measured voltage and current, to a controller 100 as described below.

Also, the power supply 30 may include a DC power supply 32 coupled to the plasma processing chamber 10. The DC power supply 32 includes a first DC generator 32a and a second DC generator 32b. In one embodiment, the first DC generator 32a is connected to the conductive member of the substrate support 11 and is configured to generate a first DC signal. The generated first DC signal is applied to the conductive member of the substrate support 11. In one embodiment, the first DC signal may be applied to another electrode such as an electrode in the electrostatic chuck. In one embodiment, the second DC generator 32b is connected to the conductive member of the shower head 13 and is configured to generate a second DC signal. The generated second DC signal is applied to the conductive member of the shower head 13. In various embodiments, the first and second DC signals may be pulsed. The first and second DC generators 32a and 32b may be provided in addition to the RF power supply 31, or the first DC generator 32a may be provided instead of the second RF generator 31b.

The exhaust system 40 may be connected to, for example, a gas exhaust port 10e formed at the bottom of the plasma processing chamber 10. The exhaust system 40 may include a pressure regulation valve and a vacuum pump. By the pressure regulation valve, the pressure within the plasma processing space 10s is adjusted. The vacuum pump may include a turbomolecular pump, a dry pump or a combination thereof.

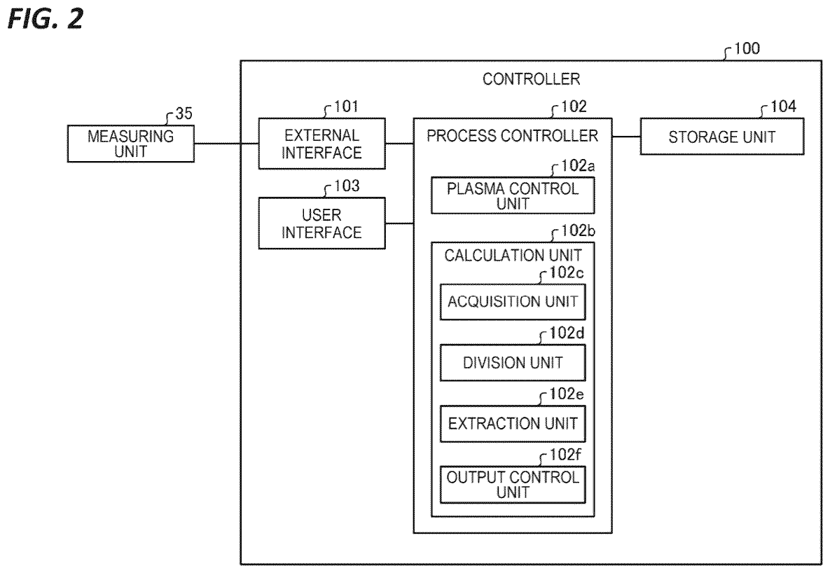

The plasma processing apparatus 1 configured as described above further includes the controller 100 as described below. FIG. 2 is a block diagram illustrating an example of the functional configuration of the controller in the present embodiment. The operation of the plasma processing apparatus 1 illustrated in FIG. 1 is controlled by the controller 100.

The controller 100 is, for example, a computer, and controls each unit of the plasma processing apparatus 1. The operation of the plasma processing apparatus 1 is comprehensively controlled by the controller 100. The controller 100 controls the plasma processing apparatus 1 to execute various processes described in the present disclosure. The controller 100 is provided with an external interface 101, a process controller 102, a user interface 103, and a storage unit 104.

The external interface 101 is capable of communicating with each unit of the plasma processing apparatus 1 and inputs/outputs various data. For example, the measuring unit 35 measures voltage and current of the plasma processing apparatus 1 and generates signals indicating the voltage and current, which are input into the external interface 101.

The process controller 102 includes a central processing unit (CPU) and controls each unit of the plasma processing apparatus 1.

The user interface 103 includes a keyboard through which a process manager performs an input operation of commands. The input commands are used to manage the plasma processing apparatus 1, or to control a display that visualizes and displays the operating status of the plasma processing apparatus 1.

The storage unit 104 stores a control program (software) for realizing various processings to be executed by the plasma processing apparatus 1 under the control of the process controller 102, or a recipe in which processing condition data, are stored. As the control program or the recipe, those stored in, for example, a computer-readable computer recording medium (e.g., a hard disk, an optical disc such as a DVD, a flexible disk, a semiconductor memory, or the like) may be used. Also, the control program or the recipe may also be transmitted from other devices at any time via, for example, a dedicated line or other connections, and used online.

The process controller 102 has an internal memory for storing programs or data, reads the control program stored in the storage unit 104, and executes processing of the read control program. The process controller 102 functions as various processors when executing the control program. For example, the process controller 102 has the functions of a plasma control unit 102a and a calculation unit 102b. In the present embodiment, as an example, descriptions are made in cases where the process controller 102 has the functions of the plasma control unit 102a and the calculation unit 102b. However, the functions of the plasma control unit 102a and the calculation unit 102b may be realized by a plurality of controllers in a distributive manner.

The plasma control unit 102a controls plasma processing. For example, the plasma control unit 102a controls the exhaust system 40 to exhaust the inside of the plasma processing chamber 10 to a predetermined degree of vacuum. The plasma control unit 102a controls the gas supply 20 to introduce a processing gas from the gas supply 20 into the plasma processing space 10s. The plasma control unit 102a controls the power supply 30 to supply a source RF signal and a bias RF signal from the first RF generator 31a and the second RF generator 31b in accordance with the introduction of the processing gas, so that plasma is generated within the plasma processing chamber 10.

The plasma processing apparatus 1 according to the present embodiment performs, for example, cycle etching. The plasma control unit 102a controls the RF power supply 31 to supply high-frequency power from the RF power supply 31 in a pulsed form. The RF power supply 31 supplies at least one of a source RF signal and a bias RF signal in a pulsed form. For example, the plasma control unit 102a controls the RF power supply 31 to supply a source RF signal and a bias RF signal in a pulsed form, from the first RF generator 31a and the second RF generator 31b, respectively. The frequency of a pulse by which the supply of the source RF signal and the bias RF signal is turned ON/OFF is, for example, 100 Hz to 10 kHz. Hereinafter, between the source RF signal and the bias RF signal, the source RF signal with a higher frequency is also referred to as HF (High Frequency), and the bias RF signal with a lower frequency is also referred to as LF (Low Frequency).

The calculation unit 102b calculates statistical values to be used for monitoring, and the like, as an index of the process state, from the voltage and current of the signal input from the measuring unit 35. As for the statistical values, for example, an average, a variance, and the like, are used. The calculated statistical values can be used for, for example, endpoint detection, feedback control to the RF power supply 31, abnormality detection, and the like. The calculation unit 102b has an acquisition unit 102c, a division unit 102d, an extraction unit 102e, and an output control unit 102f.

The acquisition unit 102c acquires a first data group for a predetermined time period based on the signal input from the measuring unit 35 via the external interface 101. In the following description, as the first data group, for example, a data group of 2000 points is used, which is obtained by sampling the pulse waveform of the voltage of the signal input from the measuring unit 35, at a sampling frequency of 100 kHz for a predetermined period of 20 ms (a predetermined cycle of 100 ms, and a data acquisition period of 20 s). As the first data group, a data group of a data set in which data pieces such as a voltage and a current are combined may be used. The acquisition unit 102c outputs the acquired first data group to the division unit 102d.

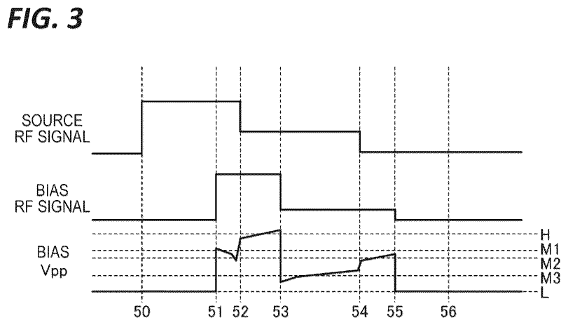

Here, descriptions will be made on the pulse waveform of the voltage of the signal input from the measuring unit 35, by using FIG. 3. FIG. 3 is a view illustrating an example of a waveform of a bias voltage when a plurality of RF signals is supplied. As illustrated in FIG. 3, when each of the source RF signal and the bias RF signal is supplied in a pulse waveform having a plurality of levels, the voltage Vpp on the substrate W to be monitored, that is, the bias Vpp which is the voltage of the signal measured by the measuring unit 35, also has a plurality of levels. In the example of FIG. 3, the source RF signal vertically rises to an H level at a time 50, vertically falls to an M level at a time 52, and vertically falls to an L level at a time 54. Also, the bias RF signal vertically rises to an H level at a time 51, vertically falls to an M level at timing 53, and vertically falls to an L level at a time 55. The bias Vpp is influenced by not only the bias RF signal but also the source RF signal, and thus vertically rises to an M1 level at a time 51, vertically falls to an M2 level until immediately before a time 52, and then vertically rises to an H level at timing 52. Also, the bias Vpp vertically falls to an M3 level with overshooting at a time 53, and vertically rises to an M2 level at a time 54. Then, the bias Vpp vertically falls to an L level at timing 55. As illustrated at timing 56, when the source RF signal and the bias RF signal are not supplied, the bias Vpp is at the L level. In the present embodiment, in a pulse waveform having a plurality of levels as in the above described bias Vpp, a level value for each level is obtained. In the following description, the value calculated for each level, for example, the voltage value of each level is expressed as a level value.

Referring back to description of FIG. 2, when the first data group is input from the acquisition unit 102c, the division unit 102d divides the first data group into groups according to the voltage Vpp, that is, each data value. For example, the division unit 102d calculates an average value of the first data group, and divides the first data group into a plurality of groups based on the calculated average value. Also, the division unit 102d calculates an average value of each separate group, and further divides each group into a plurality of groups based on the calculated average value. The division unit 102d repeats performing such group division until groups equal to or greater than a desired number of levels are obtained.

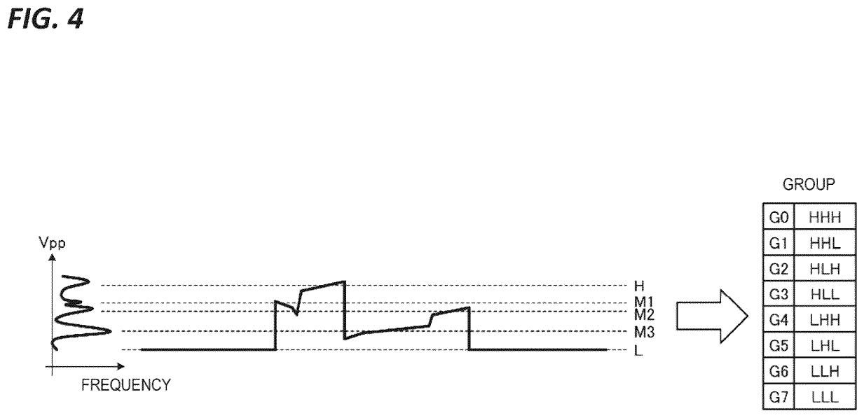

Here, descriptions will be made on group division of the first data group by using FIGS. 4 to 6. FIG. 4 is a view illustrating the outline of group division in the present embodiment. As illustrated in FIG. 4, for example, regarding the number of data points in the pulse waveform of the bias Vpp, that is, 2000 points sampled by the acquisition unit 102c, it can be found that there are five levels of H, M1 to M3, and L from a frequency distribution. The number of levels may also be obtained in advance based on the pulse waveforms of the source RF signal and the bias RF signal to be supplied. When an original data group is divided into two through one grouping, in order to cover five levels, the division unit 102d needs to divide the group into 2ⁿ (n=3) groups, that is, eight groups G0 to G7, and performs the grouping n=3 times.

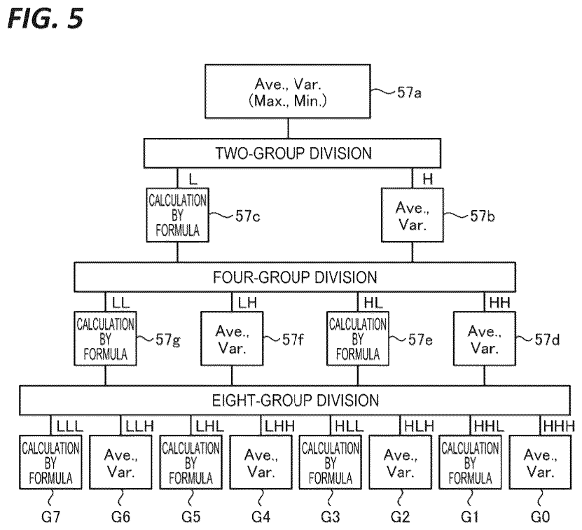

FIG. 5 is a view illustrating an example of group division in the present embodiment. As illustrated in FIG. 5, first, the division unit 102d calculates the average value (Ave.) of a first data group 57a. As illustrated in FIG. 5, at this time, the division unit 102d may calculate the variance (Var.), and may detect the maximum value (Max.) and the minimum value (Min.). Here, the division unit 102d calculates the average value or the variance by loop calculation with the number of data points of the first data group 57a as N, the sum as Sum, and the sum of squares as SumSq. By using the average value of the first data group 57a as a threshold value, the division unit 102d divides the first data group 57a into a group 57b equal to or greater than the average value and a group 57c less than the average value.

Next, the division unit 102d calculates the average value (Ave.) of the group 57b. The division unit 102d may calculate the variance (Var.) in the same manner as in the case of the first data group 57a. Regarding the group 57b, the division unit 102d calculates the average value or the variance by loop calculation with the number of data points as NH, the sum as SumH, and the sum of squares as SumSqH.

Meanwhile, the division unit 102d calculates the number of data points NL of the group 57c, the sum SumL, and the sum of squares SumSqL from the results of the loop calculation for the first data group 57a and the group 57b. That is, the division unit 102d calculates the number of data points NL, the sum SumL and the sum of squares SumSqL by using formulas in which the number of data points NH of the group 57b, the sum SumH and the sum of squares SumSqH are subtracted from the number of data points N of the first data group 57a, the sum Sum and the sum of squares SumSq, respectively. The division unit 102d calculates the average value (Ave.) of the group 57c based on the number of data points NL, the sum SumL and the sum of squares SumSqL calculated by the formulas. The division unit 102d may calculate the variance (Var.) in the same manner as in the case of the group 57b. These may be expressed by the following formulas (1) to (5). The average value or the variance of the group 57c may be calculated by loop calculation, and the average value or the variance of the group 57b may be calculated by formulas. In this case, formulas in which L and H of the formulas (1) to (5) are interchanged are used.

Number of data points NL=N−NH (1)

Sum SumL=Sum−SumH (2)

Sum of squares SumSqL=SumSq−SumSqH=(3)

Average value AveL=SumH/NH (4)

Variance VarL=SumSqL/NL−AveLxAveL (5)

Next, by using the average value of the group 57b as a threshold value, the division unit 102d divides the group 57b into a group 57d equal to or greater than the average value and a group 57e less than the average value. Also, by using the average value of the group 57c as a threshold value, the division unit 102d divides the group 57c into a group 57f equal to or greater than the average value and a group 57g less than the average value. That is, at this point in time, the first data group 57a is divided into four groups. The division unit 102d calculates the average value or the variance of each of the groups 57d to 57g in the same manner as for the groups 57b and 57c. The calculation of the average value or the variance is similar to that in the above-described case of the groups 57b and 57c, and thus the explanation thereof is omitted.

Similarly, the division unit 102d divides each of the four groups 57d to 57g to obtain eight separate groups G0 to G7. For the groups G0 to G7, the division unit 102d calculates the average value or variance of each of the groups G0 to G7 in the same manner as for the groups 57b to 57g. Here, the calculation of the average value or the variance is similar to that in the above-described case of the groups 57d to 57g, and thus, the explanation thereof is omitted.

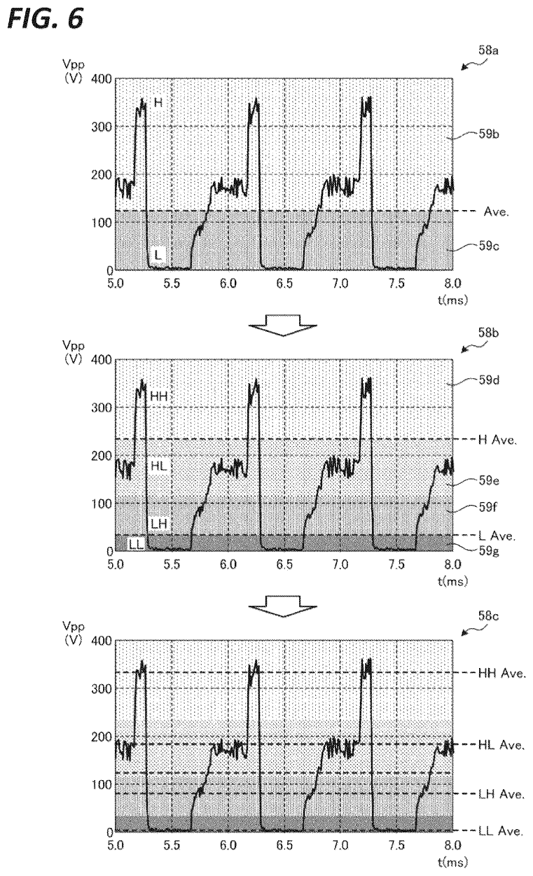

FIG. 6 is a view illustrating an example of a case where group division is performed by using the average value in the present embodiment. FIG. 6 illustrates graphs on average values which are calculated at stages, respectively, until group division into four groups 57d to 57g illustrated in FIG. 5 is performed. The pulse waveform is different from that in FIGS. 3 and 4. A graph 58a illustrates a state where division into two groups is performed by the average value of the first data group 57a. The graph 58a illustrates that the data group of the pulse waveform in an H-side region 59b is classified as the group 57b, and the data group of the pulse waveform in an L-side region 59c is classified as the group 57c.

A graph 58b illustrates a state where each of the groups 57b and 57c is divided into two groups by the average value of each of the groups 57b and 57c. The graph 58b illustrates that the data group of the pulse waveform in an HH-side region 59d is classified as the group 57d, and the data group of the pulse waveform in an HL-side region 59e is classified as the group 57e. Also, the graph 58b illustrates that the data group of the pulse waveform in an LH-side region 59f is classified as the group 57f, and the data group of the pulse waveform in an LL-side region 59g is classified as the group 57g.

A graph 58c illustrates the average value of each of the groups 57d to 57g in the graph 58b. Although not illustrated, the groups G0 to G7 (HHH to LLL) are obtained through division based on the respective average values of the groups 57d to 57g in the graph 58c. Also, the division unit 102d may not calculate the variances for the first data group 57a and the groups 57b to 57g, and then may calculate variances for the groups G0 to G7 after division into the groups G0 to G7. The division unit 102d outputs each of data groups (the groups G0 to G7) obtained through division in this manner, together with the average value and the variance of each group, to the extraction unit 102e.

Referring back to FIG. 2, when each of the data groups (the groups G0 to G7) is input from the division unit 102d, the extraction unit 102e extracts a second data group included in a valid group, from the groups G0 to G7. For example, the extraction unit 102e determines whether each group is in a transient state, based on a CV (coefficient of variation) value based on the variance and the average value of each of the groups G0 to G7 and the number of data points of each of the groups G0 to G7. That is, from the groups G0 to G7, the extraction unit 102e extracts, as a valid data group, a data group whose number of data points is larger than a predetermined threshold number of data points and whose CV value is smaller than a predetermined threshold CV value. The CV values indicate change rates of the groups G0 to G7. Also, among the groups G0 to G7, a group whose number of data points is smaller than a predetermined threshold number of data points and CV value is larger than a predetermined threshold CV value is considered as a transient group and as an invalid group, and then is not extracted. The CV values indicate change rates of the groups G0 to G7. The group G0 including the highest value is not considered as being invalid and is extracted even if the number of data points is small.

The predetermined threshold number of data points and the predetermined threshold CV value may be input from the user interface 103. Also, it is possible to use the saved inputs as a part in a control program (software) stored in the storage unit 104 or a stored recipe in which processing condition data, and the like, are stored.

Also, the extraction unit 102e compares the differences of the average values and the variances between adjacent groups, among the groups G0 to G7, and determines whether to perform integration into the same group. When the integration into the same group is determined, the extraction unit 102e consolidates the adjacent groups into one group. That is, the extraction unit 102e excludes invalid groups from the data groups (groups G0 to G7), and extracts each data group included in a valid group after integration of adjacent groups, as a second data group for which group level division has been completed. The extraction unit 102e outputs the extracted second data group to the output control unit 102f.

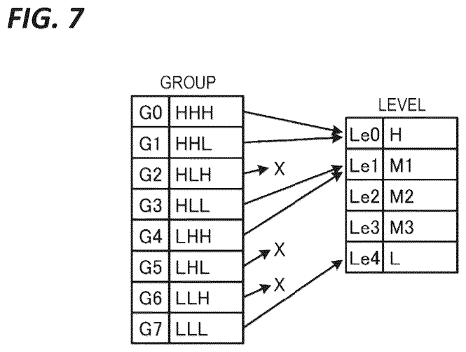

Here, descriptions are made on the extraction of a valid group by using FIG. 7. FIG. 7 is a view illustrating an example of a valid group extraction in the present embodiment. In the example of FIG. 7, among the groups G0 to G7, the groups G2, G5, and G6 are considered as transient groups and invalid groups. Also, the group G0 and the group G1 are integrated as a level Le0. Similarly, the groups G3 and G4 are integrated as a level Le1. The group G7 is independently classified as a level Le4 because the adjacent group G6 is considered to be an invalid group. Here, the level Le0 corresponds to the highest H level, and the level Le4 corresponds to the lowest L level. Also, the levels Le1 to Le3 correspond to intermediate level values M1 to M3. Also, in the example of FIG. 7, although there are no groups classified as levels Le2, and Le3, in some cases, there may be groups classified as the levels Le2, and Le3 according to the base pulse waveform. In the example of FIG. 7, there are a maximum of five levels Le0 to Le4, but the levels are not limited thereto, and the number of levels may be four or less, or may be five or more.

Referring back to FIG. 2, when the extracted second data group is input from the extraction unit 102e, the output control unit 102f outputs a statistical value for each group after level division, to the plasma control unit 102a or the user interface 103, based on the second data group. For each group, as the statistical value for each group, the output control unit 102f outputs a level value for each data value included in the first data group for a predetermined time period, by using, for example, the average value of the second data group. Also, the output control unit 102f outputs, as a duty, the ratio of the number of data points for each level value, to the plasma control unit 102a or the user interface 103. Additionally, the output control unit 102f may detect an end point or an abnormality based on these level values or duties, and may output the detection result to the plasma control unit 102a or to the user interface 103.

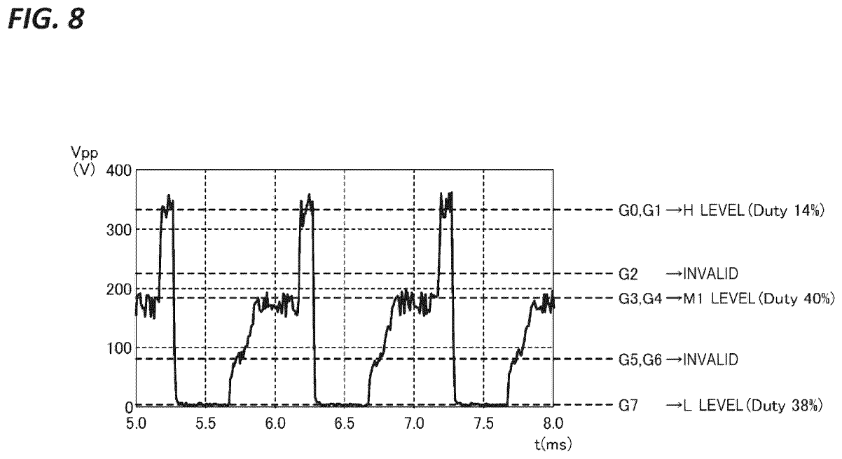

Here, descriptions are made on output statistical values by using FIG. 8. FIG. 8 is a view illustrating an example of the level value for each level calculated in the present embodiment. As illustrated in FIG. 8, regarding, for example, the pulse waveform of the voltage of the signal input from the measuring unit 35, the output control unit 102f outputs the H level of the level Le0 including the groups G0 and G1, the M1 level of the level Le1 including the groups G3 and G4, and the L level of the level Le4 including the group G7. Also, the output control unit 102f outputs values such as 14% for the H level, 40% for the M1 level, and 38% for the L level, as the duty for each level value. Although the groups G2, G5, and G6 are considered to be invalid groups, as illustrated in FIG. 8, it can be determined that the groups are in a transient period in comparison with the pulse waveform.

The plasma control unit 102a controls plasma processing based on the end point detection result based on the statistical values calculated by the calculation unit 102b. For example, when the end point of the process is detected by the calculation unit 102b, the plasma control unit 102a ends the plasma processing.

In this method, averages are used and thus values can be firmly extracted. However, if the number of points of each group is small (if the pulse-ON Duty is low), values may fluctuate. For example, in a group with only about five points per pulse, the average value fluctuates due to slight variations, in the pulse ON timing and the data acquisition timing. In such a case, the best method is to increase the sampling frequency, to increase the number of points. However, this may be difficult due to hardware constraints, and the like, in some cases.

In such a case, there is a method of providing a complementing unit (not illustrated) between the acquisition unit 102c and the division unit 102d to complement data. For example, when a point composed of an average value of two points is added (linear complementation) as an intermediate point between a data point and a data point, the same effect as that of a case in which the sampling frequency is doubled is obtained. Also, when four points are added at equal intervals by linear complementation, the same effect as that obtained by increasing the sampling frequency by five times is obtained. The complementary method is not limited to linearity, and may be polynomial complementation, exponential complementation, logarithmic complementation, and the like.

Table 1 below is an example of the magnitude of the variation in the average value when a pulse with a pulse frequency of 400 Hz and a Duty of 5% is acquired at 100 kHz sampling. In Table 1, the magnitude of the variation in the average value is expressed as four times the standard deviation divided by the average value. When there is no complementation, one group can only have about seven points per cycle of the acquired pulse. Therefore, the average value of the group without any complementation has a variation of about 1.6%. Meanwhile, it can be found that in the average value of a group to which points are added through complementation, if, for example, four or more points are added, the magnitude of the variation can be improved to one-third or less as compared to a case not having any complementation.

TABLE 1

| Condition | 4 × Standard Deviation/Average Value |
|---|---|
| No complementation | 1.6% |
| One point added | 0.8% |
| Four points added | 0.5% |
| Nine points added | 0.5% |

### [Data Calculation Method]

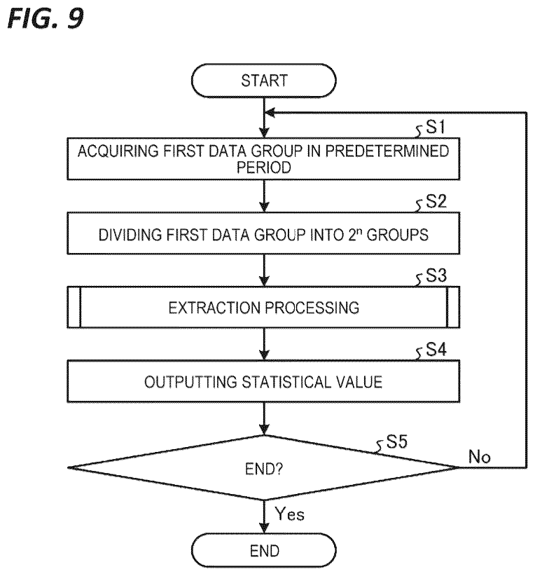

Next, descriptions will be made on data calculation processing according to the present embodiment. FIG. 9 is a flowchart illustrating an example of data calculation processing in the present embodiment.

In the data calculation processing according to the present embodiment, as an example, descriptions are made on a case where plasma processing is performed on the substrate W, which has been placed on the central region 111a of the main body 111 of the substrate support 11 (stage) in the plasma processing apparatus 1. Here, the operations related to plasma processing by the plasma control unit 102a are omitted in the description. The acquisition unit 102c of the calculation unit 102b acquires a first data group for a predetermined period based on the signal input from the measuring unit 35 (step S1). The acquisition unit 102c outputs the acquired first data group to the division unit 102d.

When the first data group is input from the acquisition unit 102c, the division unit 102d divides the first data group into 2″ (for example, n=3.) groups by using an average value (step S2). The division unit 102d divides the first data group into, for example, groups G0 to G7. The division unit 102d calculates the average value and the variance of each of the groups G0 to G7. The division unit 102d outputs each of data groups (groups G0 to G7) obtained through division in this manner, together with the average value and the variance of each group, to the extraction unit 102e.

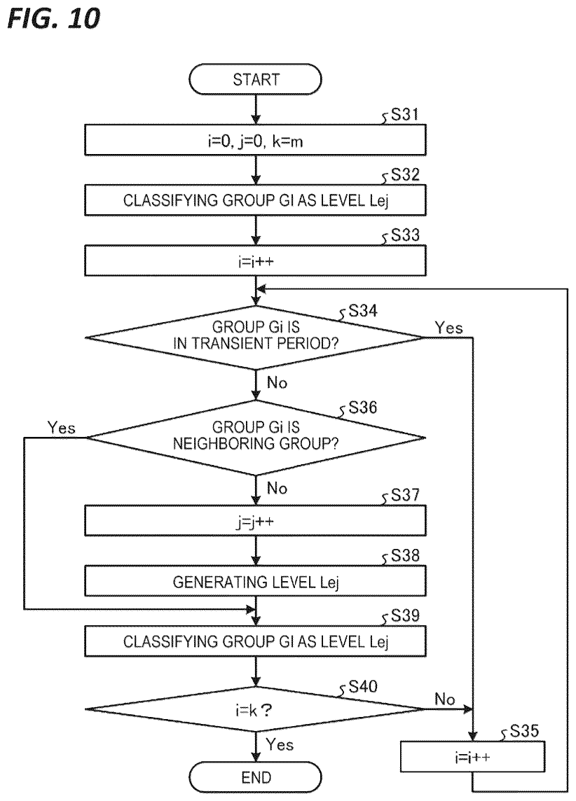

When each of data groups (the groups G0 to G7) is input together with the average value and variance of each group from the division unit 102d, the extraction unit 102e executes extraction processing (step S3). Here, the extraction processing is described with reference to FIG. 10. FIG. 10 is a flow chart illustrating an example of extraction processing in the present embodiment.

The extraction unit 102e initializes variables i, j, and k such that variable i=0, variable j=0, and variable k=m (step S31). Here, m corresponds to the number of divisions of the first data group, 2ⁿ, and m is 8 when n=3. The extraction unit 102e classifies a group Gi as a level Lej (step S32). That is, the group G0 including the highest value is classified as the level Le0. The extraction unit 102e increments the variable i (step S33).

The extraction unit 102e determines whether the group Gi is in a transient period based on the CV value of the group Gi and the number of data points of the group Gi (step S34). When it is determined that the group Gi is in a transient period (step S34: Yes), the extraction unit 102e increments the variable i (step S35), and returns to step S34.

Meanwhile, when it is determined that the group Gi is not in a transient period (step S34: No), the extraction unit 102e determines whether the group Gi is a neighboring group (step S36). When it is determined that the group Gi is not a neighboring group (step S36: No), the extraction unit 102e increments the variable j (step S37), and generates the level Lej (step S38). The extraction unit 102e classifies the group Gi as the generated level Lej (step S39). Meanwhile, when it is determined that the group Gi is a neighboring group (step S36: Yes), the extraction unit 102e proceeds to step S39 without generating the level Lej, and classifies the group Gi as the existing level Lej.

The extraction unit 102e determines whether the variable i equals to k (i=k) (step S40). When the variable i is not k (step S40: No), the extraction unit 102e proceeds to step S35. Meanwhile, when variable i equals to k (e.g., i=k) (step S40: Yes), the extraction unit 102e outputs the extracted second data group to the output control unit 102f, ends the extraction processing, and returns to the original processing.

Referring back to the description of FIG. 9, when the extracted second data group is input from the extraction unit 102e, the output control unit 102f outputs statistical values for each group after level division based on the second data group, for example, the level value and the ratio of each level, to the plasma control unit 102a (step S4). When the statistical values are output, the output control unit 102f determines whether to end the data calculation processing (step S5). When determining not to end the data calculation processing (step S5: No), the output control unit 102f returns to step S1, and repeats the data calculation processing for a predetermined period in the next cycle. Meanwhile, when determining to end the data calculation processing (step S5: Yes), the output control unit 102f ends the data calculation processing. This makes it possible to obtain the level value and the ratio of each level in a pulse waveform having a plurality of levels.

### Example 1

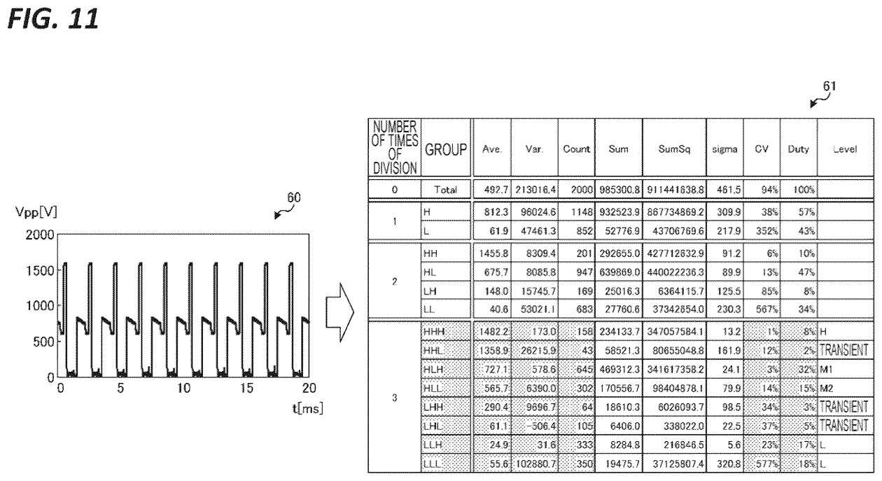

Next, as Example 1, a case where regarding plasma processing for 20 sec, the voltage Vpp on a processing target substrate W is monitored by the measuring unit 35 is described. FIG. 11 is a view illustrating an example of the one-dimensional cluster analysis result, in Example 1 according to the present embodiment. As illustrated in a graph 60 of FIG. 11, in Example 1, an RF signal obtained by pulse-modulating an RF signal of 13 MHz by four stages at 500 Hz is used as a bias RF signal. The graph 60 illustrates the voltage Vpp of the bias RF signal measured by the measuring unit 35. Also, the voltage Vpp applied to the processing target substrate W is correlated with the acceleration voltage of ions for performing processing, and becomes an important index of process stability. In Example 1, a data group of 2000 points sampled at a sampling frequency of 100 kHz every 100 ms which is a predetermined cycle, that is, a data group corresponding to 20 ms (a predetermined period) in the first half of 100 ms, is used as a first data group. Data sampling is performed without synchronization with the pulse waveform of the bias RF signal.

A table 61 of FIG. 11 is the result of the one-dimensional cluster analysis obtained by performing the above-mentioned data calculation processing on the bias RF signal of the graph 60. The table 61 includes each of the statistical values from the first data group to the third number of divisions. The table 61 includes items such as “number of times of division”, “group”, “Ave.”, “Var.”, “Count”, “Sum”, “SumSq”, “sigma”, “CV”, “Duty”, and “Level”.

The “number of times of division” indicates the number of times the division unit 102d has performed the division of grouping. “group” indicates the label of each group among data groups obtained through grouping by division. “Ave.” indicates the average value of each group. “Var.” indicates the variance of each group. “Count” indicates the number of data points belonging to each group. “Sum” indicates the sum of data belonging to each group. “SumSq” indicates the sum of squares of data belonging to each group. “sigma” indicates the standard deviation (o) in each group. “CV” indicates the CV value in each group. “Duty” indicates the ratio of each group to the first data group. The “Level” indicates voltage level values such as H, M1, M2, and L when a second data group obtained through completion of level division by the extraction unit 102e corresponds to each level, and indicates a transient state in a case of a transient period. The shaded portions in the table 61 correspond to values output as statistical values by the output control unit 102f.

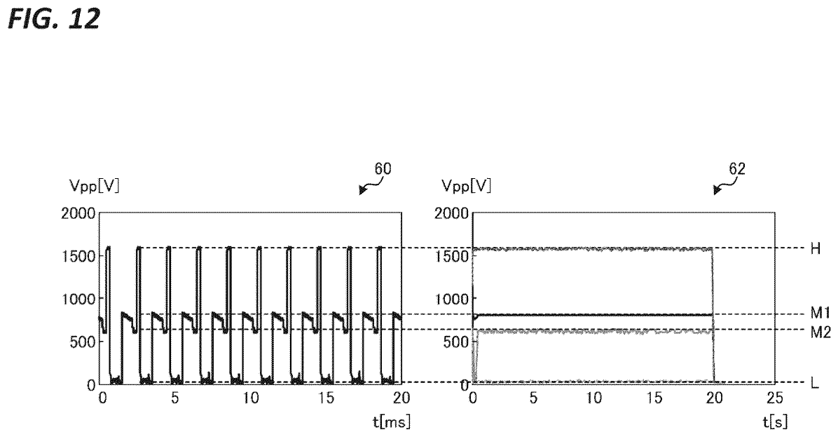

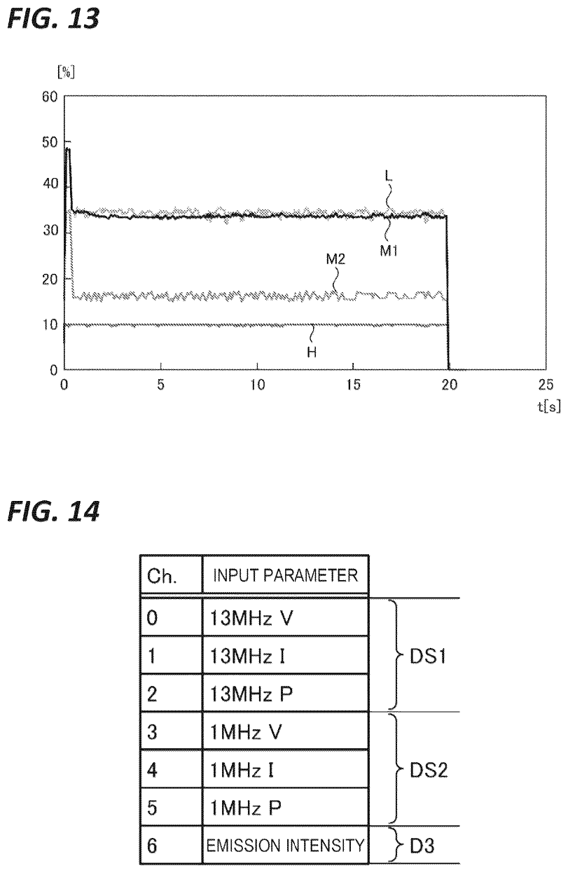

FIG. 12 is a view illustrating an example of the result when the one-dimensional cluster analysis of Example 1 is repeated a predetermined number of times. FIG. 13 is a view illustrating an example of the ratio of the number of data points for each level value in Example 1. In a graph 62 illustrated in FIG. 12, the data calculation processing of the graph 60, which is one portion of a predetermined period (20 ms), is repeated at every predetermined cycle (100 ms) 200 or more times corresponding to plasma processing for 20 seconds, and then the average value of each group classified as each level is plotted as a level value. As illustrated in the graph 62, the plotted level values are four level values, an H level, an M1 level, an M2 level and an L level. Also, as illustrated in FIG. 13, the duty, which is the ratio of the number of data points corresponding to each level value of the graph 62, may be plotted and graphed. The output control unit 102f may detect the end point or abnormality based on the changes in plot values at each level value. In this way, in Example 1, the level value and the duty for each level in the pulse waveform may be obtained. Also, by continuing the cluster analysis of Example 1 during the process, it is possible to obtain changes in the process step for the level value of each level. Additionally, the duty ratio may be obtained from the number of data points for the level value at each level.

### Example 2

Next, descriptions will be made for the case of Example 2, where an RF signal of 1 MHz is further supplied as a bias RF signal in addition to conditions of Example 1. In Example 2, the voltage V, the current I, and the phase difference P are monitored by the measuring unit 35, and also the emission intensity of plasma is monitored by using, for example, a high-speed photodiode through an observation window (not illustrated) which is provided in the plasma processing chamber 10. The voltage V corresponds to the voltage Vpp of Example 1.

FIG. 14 is a view illustrating an example of the relationship between the data set and group division in Example 2. As illustrated in FIG. 14, in Example 2, the calculation unit 102b treats the voltage V, the current I, and the phase difference P of the 13 MHz bias RF signal, which are input parameters of channels Ch. 0 to 2, as a data set DS1, and divides the data set DS1 into a plurality of groups based on the value of the voltage V of the 13 MHz bias RF signal. Here, the current I and the phase difference P are divided into a plurality of groups such that a set is formed together with the corresponding voltage V. That is, the data set DS1 is a first data group of a data set including a plurality of types of related data. Also, the calculation unit 102b divides the data set DS1 into a plurality of groups based on a specific type of data (voltage V).

Similarly, the calculation unit 102b treats the voltage V, the current I, and the phase difference P of the 1 MHz bias RF signal, which are input parameters of channels Ch. 3 to 5, as a data set DS2, and divides the data set DS2 into a plurality of groups based on the value of the voltage V of the 1 MHz bias RF signal. Here, the current I and the phase difference P are divided into a plurality of groups such that a set is formed together with the corresponding voltage V. That is, the data set DS2 is a first data group of a data set including a plurality of types of related data. Also, the calculation unit 102b divides the data set DS2 into a plurality of groups based on a specific type of data (voltage V). Additionally, the calculation unit 102b performs group division on a data group D3 alone as a first data group in relation to the emission intensity which is an input parameter of a channel Ch. 6. That is, the calculation unit 102b divides the first data group into a plurality of groups for each type of input parameter.

Based on a second data group obtained by grouping of each of the data sets DS1 and DS2, the calculation unit 102b calculates, for example, an impedance Z as each parameter, and outputs the calculated impedance Z as a statistical value. That is, the calculation unit 102b calculates the impedance Z based on the voltage V, the current I and the phase difference P which are acquired at once. The calculation unit 102b performs level division on the current I and the phase difference P of a second input parameter by using a first input parameter, and then calculates the impedance Z as a third parameter by using the first parameter and the second parameter. Also, the calculation unit 102b calculates, for example, a level value of emission intensity as a parameter based on a second data group obtained by grouping of the data group D3. As the output corresponding to the graph 62 of FIG. 12, the calculation unit 102b outputs, as statistical values, data capable of creating, for example, a graph illustrating level values of the voltage V, the current I and the impedance Z corresponding to the 13 MHz bias RF signal, a graph illustrating level values of the voltage V, the current I and the impedance Z corresponding to the 1 MHz bias RF signal, and a graph illustrating level values of emission intensity. In this way, in Example 2, cluster analysis may also be easily performed on two or more-dimensional data by combining one-dimensional cluster analyses.

### Example 3

Next, descriptions will be made in the case of Example 3, in which two types of group division are performed on emission intensity in the same configuration as in Example 2.

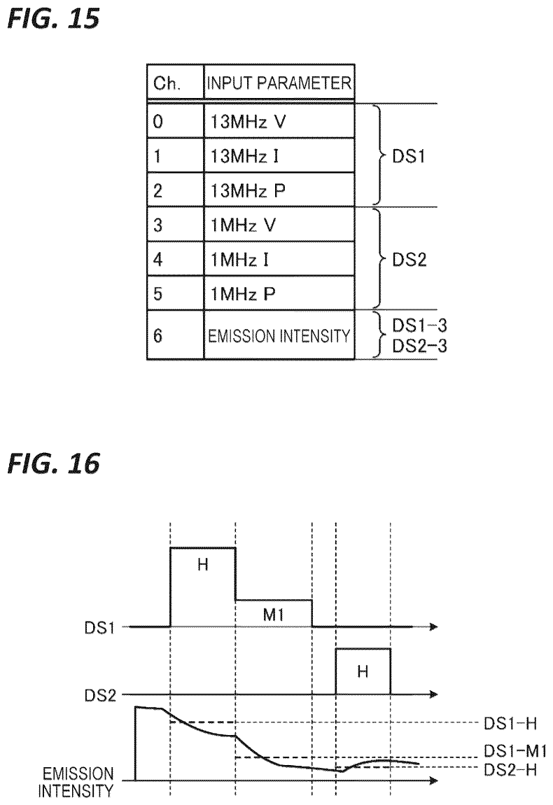

FIG. 15 is a view illustrating an example of the relationship between the data set and group division in Example 3. As illustrated in FIG. 15, in Example 3, regarding the emission intensity which is an input parameter of the channel Ch. 6, the calculation unit 102b divides a data set DS1-3 into a plurality of groups based on the value of the voltage V of the 13 MHz bias RF signal. Similarly, regarding the emission intensity, the calculation unit 102b divides a data set DS2-3 into a plurality of groups based on the value of the voltage V of the 1 MHz bias RF signal. That is, the first data group is a data group corresponding to three types of input parameters, 13 MHz, 1 MHz and emission intensity. Also, the calculation unit 102b divides a data group in the first data group corresponding to one type of input parameter (emission intensity), into a plurality of groups, for each of the other two types of input parameters (13 MHz, and 1 MHz).

Based on a second data group obtained by grouping of each of the data sets DS1, DS2, DS1-3, and DS2-3, the calculation unit 102b calculates each parameter, and outputs the calculated parameter as a statistical value.

FIG. 16 is a view illustrating an example of the level value of each level calculated in Example 3. FIG. 16 illustrates the level value of the voltage V in the data set DS1, the level value of the voltage V in the data set DS2, and the level values of emission intensity based on the emission intensity and the data sets DS1-3 and DS2-3. In the graph of the emission intensity in FIG. 16, DS1-H represents an H level based on the data set DS1-3, DS1-M1 represents an M1 level based on the data set DS1-3, and DS2-H represents an H level based on the data set DS2-3. That is, as the output corresponding to the graph 62 of FIG. 12, the calculation unit 102b outputs, as statistical values, data capable of creating, for example, a graph illustrating level values of the voltage V, the current I, and the impedance Z corresponding to the 13 MHz bias RF signal, and a graph illustrating level values of the voltage V, the current I and the impedance Z corresponding to the 1 MHz bias RF signal. Also, as the output corresponding to the graph 62 of FIG. 12, the calculation unit 102b outputs, as statistical values, data capable of creating, for example, a graph illustrating the level value of emission intensity corresponding to the level value of the voltage V of the 13 MHz bias RF signal and a graph illustrating the level value of emission intensity corresponding to the level value of the voltage V of the 1 MHz bias RF signal. In this manner, in Example 3, as in Example 2, cluster analysis may also be performed on two or more dimensional data by combining one-dimensional cluster analyses.

As discussed above, according to the present embodiment, the calculation unit 102b acquires a first data group for a predetermined period, divides the acquired first data group into a plurality of groups according to a range of each data value included in the first data group, extracts a second data group included in a valid group, from the separate groups, and outputs a statistical value for each of the groups based on the extracted second data group. As a result, it is possible to obtain a level value and a ratio of each level in a pulse waveform having a plurality of levels.

Also, according to the present embodiment, after the first data group is acquired, the calculation unit 102b calculates data that complements adjacent data in the acquired first data group, and adds the calculated data to the first data group. As a result, it is possible to suppress the average value of the group from fluctuating.

Also, according to the present embodiment, the calculation unit 102b calculates an average value of the first data group, and divides the first data group into the plurality of groups based on the calculated average value. As a result, it is possible to obtain a level value and a ratio of each level in a pulse waveform having a plurality of levels.

Also, according to the present embodiment, the calculation unit 102b calculates an average value for each of the groups, and further divides the group into a plurality of groups based on the calculated average value. As a result, it is possible to obtain a level value and a ratio of each level in a pulse waveform having a plurality of levels.

Also, according to the present embodiment, the calculation unit 102b divides the first data group or the group into two groups, and then calculates the average value of one group by loop calculation, and calculates the average value of the other group based on the average value before division and the average value calculated for one group. As a result, a calculation load may be reduced.

Also, according to the present embodiment, the calculation unit 102b calculates a variance for each of the plurality of groups, and then considers a group determined to be in a transient state, as an invalid group and does not extract the group, based on a CV value based on the calculated variance for each of the groups and the average value for each of the groups and the number of data points for each of the groups. As a result, it is possible to suppress erroneous detection of the level.

Also, according to the present embodiment, the calculation unit 102b compares differences of the average values and the variances between the adjacent groups, and consolidates the adjacent groups into one group when integration into the same group is determined. As a result, groups belonging to the same level may be integrated.

Also, according to the present embodiment, for each of the groups, the calculation unit 102b outputs an average value of the second data group, as a level value of each data value included in the first data group for the predetermined period. As a result, it is possible to obtain a level value at each level.

Also, according to the present embodiment, the calculation unit 102b outputs a ratio of the number of data points for each level value. As a result, it is possible to obtain the ratio (duty) of each level value in the first data group.

Also, according to the present embodiment, the calculation unit 102b performs division into 2ⁿ or more groups when the number of the level values is n. As a result, it is possible to obtain level values in the first data group without omission.

The number of level values: “n” may be input from the user interface 103, and it is possible to use those saved as a part in a control program (software) stored in the storage 140 or a stored recipe in which processing condition data are stored. Also, automatic calculation may be performed by a combination of pulse timings of a bias RF signal and a source RF signal both in the processing condition data.

Also, according to the present embodiment, the calculation unit 102b acquires the first data group for the predetermined period that is repeated at a predetermined cycle. As a result, it is possible to continuously obtain the level value and the ratio of each level in the pulse waveform having a plurality of levels.

Also, according to the present embodiment, the first data group is a data group of a data set including a plurality of types of related data. Also, the calculation unit 102b divides the data set into the plurality of groups based on a specific type of data, calculates a parameter for each data set based on the second data group corresponding to the data set, and outputs the calculated parameter as the statistical value for each of the groups. As a result, it is possible to easily perform cluster analysis on two or more-dimensional data by combining one-dimensional cluster analyses.

Also, according to the present embodiment, the plurality of types of related data is a voltage, a current and a phase difference of radio-frequency power supplied to an electrode in a plasma processing container. As a result, it is possible to calculate the impedance of plasma on the substrate W being processed.

Also, according to the present embodiment, the first data group is a data group corresponding to a plurality of types of input parameters. Also, the calculation unit 102b divides the first data group into the plurality of groups for each of the types of the input parameters. As a result, it is possible to obtain the level value of each level and the ratio for each of the types of the input parameters.

Also, according to the present embodiment, the first data group is a data group corresponding to three types of input parameters. Also, the calculation unit 102b divides a data group in the first data group corresponding to one type of input parameter, into the plurality of groups, for each of the other two types of input parameters. As a result, it is possible to obtain the level value and the ratio of each level according to the relationship between the input parameters.

Also, according to the present embodiment, the input parameters are of a frequency of the radio-frequency power supplied to the electrode in the plasma processing container and emission intensity of plasma in the plasma processing container. As a result, it is possible to obtain the level value and ratio of emission intensity for each frequency of the radio-frequency power.

Embodiments disclosed herein should be considered to be illustrative and not restrictive in all aspects. The above embodiments may be omitted, replaced, or modified in various forms without departing from the scope and spirit of the appended claims.

Also, in the above embodiments, as an example, descriptions have been made on a case where the measuring unit 35 is provided on the conductive portion 33b connected to the substrate support 11. However, the present disclosure is not limited thereto. The measuring unit 35 may be provided on an electrode disposed in the plasma processing chamber 10 or wiring connected to the electrode in order to measure the state of plasma in the plasma processing chamber 10. For example, the measuring unit 35 may be provided on the conductive portion 33a connected to the conductive member of the shower head 13. Also, a measuring electrode may be disposed in the plasma processing chamber 10, and the measuring unit 35 may be provided on the electrode or wire-connected to the electrode. Also, in the present embodiment, the measuring unit 35 is provided on the conductive portion 33b closer to the substrate support 11 than the impedance matching circuit 34b. This allows the measuring unit 35 to measure the plasma state in the plasma processing chamber 10.

Also, in the above embodiments, as an example, descriptions have been made on the capacitively coupled plasma processing apparatus 1 that performs processing such as etching on the substrate W by using capacitively coupled plasma as a plasma source, but the disclosed technology is not limited thereto. As long as the apparatus performs processing on the substrate W by using plasma, a plasma source is not limited to capacitively coupled plasma, and, for example, any plasma source such as capacitively coupled plasma, microwave plasma, and magnetron plasma may be used.

Also, in the above embodiments, as the first data group, a data group of 2000 points sampled from the pulse waveform of the voltage of the signal input from the measuring unit 35 is used, but the present disclosure is not limited thereto. For example, the processing results (such as dimensions or etching depths) of a substrate etched by the plasma processing apparatus 1 may be sampled for each of substrates. The acquired first data group may be divided into a plurality of groups so that a second data group is extracted. Then, a statistical value may be output for each group based on the extracted second data group. Then, the variation in the processing results may be divided into groups, and the cause of the variation may be identified based on the output statistical value of each group.

Also, in the above embodiments, the data calculation method is executed by the computer included in the controller 100, but the present disclosure is not limited thereto.

For example, the computer may include a field programmable gate array (FPGA) exclusively programmed for data calculation or an exclusively designed gate array. Also, the acquired data group may be processed using spreadsheet software such as Microsoft Excel®, or may be manually calculated.

Each component for each device illustrated in drawings does not necessarily need to be physically configured as illustrated in drawings. That is, specific forms of distribution and integration in each device are not limited to those illustrated in drawings, and all or a part thereof may be configured by being functionally or physically distributed and integrated in any units depending on various loads or usage status, and the like.

Additionally, regarding various processing functions performed by each device, all or an optional portion thereof may be executed on a CPU (or a microcomputer such as a micro processing unit (MPU), or a micro controller unit (MCU)). Also, regarding various processing functions, all or an optional portion thereof may be executed on a program analyzed and executed by a CPU (or a microcomputer such as an MPU or an MCU), or on hardware using wired logic.

The present disclosure may also take the following configurations.

### Example Configurations

(1) A data calculation method including: acquiring a first data group for a predetermined period; dividing the first data group into a plurality of groups according to a range of each data value included in the first data group; extracting a second data group included in a valid group among the plurality of groups; and outputting a statistical value for each of the plurality of groups, based on the extracted second data group.

(2) The data calculation method according to (1), further including: after the acquiring, calculating data that is a complement between adjacent data pieces in the first data group; and adding the calculated data to the first data group.

(3) The data calculation method according to (1) or (2), in which in the dividing, an average value of the first data group is calculated, and the first data group is divided into the plurality of groups based on the calculated average value.

(4) The data calculation method according to (3), in which in the dividing, an average value is calculated for each of the groups, and each of the plurality of groups is further divided into a plurality of groups based on the calculated average value.

(5) The data calculation method according to (3) or (4), in which in the dividing, the first data group or each of the plurality of groups is divided into two groups, and then the average value of one group is calculated by loop calculation, and the average value of the other group is calculated based on the average value before division and the average value calculated for the one group.

(6) The data calculation method according to any one of (3) to (5), in which in the dividing, a variance is calculated for each of the plurality of groups, and in the extracting, a group determined to be in a transient state is considered as an invalid group and is not extracted based on a CV value based on the calculated variance for each of the groups and the average value for each of the groups and the number of data points for each of the groups.

(7) The data calculation method according to (6), in which in the extracting, differences of the average values and the variances are compared between the adjacent groups, and then when integration into the same group is determined, the adjacent groups are integrated as one group.

(8) The data calculation method according to any one of (1) to (7), in which in the outputting, for each of the plurality of groups, an average value of the second data group is output as a level value of each data value included in the first data group for the predetermined period.

(9) The data calculation method according to (8), in which in the outputting, a ratio of the number of data points is output for each level value.

(10) The data calculation method according to (8) or (9), in which in the dividing, division into 2ⁿ or more groups is performed when the number of the levels is n.

(11) The data calculation method according to any one of (1) to (10), in which in the acquiring, the first data group is acquired for the predetermined period that is repeated at a predetermined cycle.

(12) The data calculation method according to any one of (1) to (11), in which the first data group is a data group of a data set including a plurality of types of related data, in the dividing, the data set is divided into the plurality of groups based on a specific type of data, and in the outputting, a parameter is calculated for each data set based on the second data group corresponding to the data set, and the calculated parameter is output as the statistical value for each of the plurality of groups.

(13) The data calculation method according to (12), in which the plurality of types of related data is a voltage, a current and a phase difference of radio-frequency power supplied to an electrode in a plasma processing container.

(14) The data calculation method according to any one of (1) to (13), in which the first data group is a data group corresponding to a plurality of types of input parameters, and in the dividing, the first data group is divided into the plurality of groups for each of the types of the input parameters.

(15) The data calculation method according to any one of (1) to (14), in which the first data group is a data group corresponding to three types of input parameters, and in the dividing, a data group in the first data group corresponding to one type of input parameter is divided into the plurality of groups, for each of the other two types of input parameters.

(16) The data calculation method according to (14) or (15), in which the input parameters are a frequency of the radio-frequency power supplied to the electrode in the plasma processing container, and emission intensity of plasma in the plasma processing container.

(17) A substrate processing apparatus including: a measuring unit that measures data related to processing on a substrate; and a controller, in which the controller is configured to control the substrate processing apparatus to acquire a first data group for a predetermined period from the measuring unit, the controller is configured to control the substrate processing apparatus to divide the acquired first data group into a plurality of groups according to a range of each data value included in the first data group, the controller is configured to control the substrate processing apparatus to extract a second data group included in a valid group among the plurality of groups, and the controller is configured to control the substrate processing apparatus to output a statistical value for each of the plurality of groups, based on the extracted second data group.

According to the present disclosure, it is possible to obtain a level value and a ratio of each level in a pulse waveform having a plurality of levels.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A data calculation method comprising:
acquiring, by a processor, a first data group for a predetermined period;
dividing, by the processor, the first data group into a plurality of groups according to a range of each data value included in the first data group;
extracting, from a memory, a second data group included in a valid group among the plurality of groups; and
outputting, to a user interface, a statistical value for each of the plurality of groups based on the second data group.

2. The data calculation method according to claim 1, further comprising:
after the acquiring, calculating, by the processor, data that complements adjacent data in the first data group, thereby adding the calculated data to the first data group.

3. The data calculation method according to claim 1, wherein in the dividing, an average value of the first data group is calculated, and the first data group is divided into the plurality of groups based on the calculated average value.

4. The data calculation method according to claim 3, wherein in the dividing, an average value is calculated for each of the plurality of groups, and each of the plurality of groups is further divided into a plurality of groups based on the calculated average value.

5. The data calculation method according to claim 3, wherein in the dividing, the first data group or each of the plurality of groups is divided into two groups, and then an average value of one group of the two groups is calculated by loop calculation, and an average value of a remaining group of the two groups is calculated based on the average value before division and the average value calculated for the one group.

6. The data calculation method according to claim 3, wherein in the dividing, a variance is calculated for each of the plurality of groups, and
in the extracting, a group that is larger than a predetermined reference value of a coefficient of variation (CV) value and smaller than a predetermined reference value of data points is considered as an invalid group and is not extracted, based on the CV value based on the calculated variance for each of the plurality of groups, the average value for each of the plurality of groups, and the number of data points for each of the plurality of groups.

7. The data calculation method according to claim 6, wherein in the extracting, a group including a highest value is extracted among the plurality of groups.

8. The data calculation method according to claim 6, wherein in the extracting, differences of the average values and the variances are compared between the adjacent groups, and then when integration into the same group is determined, the adjacent groups are integrated as one group.

9. The data calculation method according to claim 1, wherein in the outputting, for each of the plurality of groups, an average value of the second data group is output as a level value of each data value included in the first data group for the predetermined period.

10. The data calculation method according to claim 9, wherein in the outputting, a ratio of the number of data points is output for each level value.

11. The data calculation method according to claim 9, wherein in the dividing, division into 2ⁿ or more groups is performed when the number of the levels is n.

12. The data calculation method according to claim 1, wherein in the acquiring, the first data group is acquired for the predetermined period that is repeated at a predetermined cycle.

13. The data calculation method according to claim 1, wherein the first data group is a data group of a data set including a plurality of types of related data,
in the dividing, the data set is divided into the plurality of groups based on a specific type of data, and
in the outputting, a parameter is calculated for each data set based on the second data group corresponding to the data set, and the calculated parameter is output as the statistical value for each of the plurality of groups.

14. The data calculation method according to claim 13, wherein the plurality of types of related data is a voltage, a current, and a phase difference of radio-frequency power supplied to an electrode in a plasma processing container.

15. The data calculation method according to claim 1, wherein the first data group is a data group corresponding to a plurality of types of input parameters, and
in the dividing, the first data group is divided into the plurality of groups for each of the types of the input parameters.

16. The data calculation method according to claim 1, wherein the first data group is a data group corresponding to three types of input parameters, and
in the dividing, a data group in the first data group corresponding to one type of input parameter is divided into the plurality of groups, for each of the other two types of input parameters.

17. The data calculation method according to claim 15, wherein the input parameters are a frequency of the radio-frequency power supplied to the electrode in the plasma processing container, and emission intensity of plasma in the plasma processing container.

18. A substrate processing apparatus comprising:
a measuring unit including a probe that measures data related to processing on a substrate; and
a controller that controls an overall operation of the substrate processing apparatus using the data and configured to:
acquire a first data group for a predetermined period from the data,
divide the first data group into a plurality of groups according to a range of each data value included in the first data group,
extract a second data group included in a valid group among the plurality of groups, and
output a statistical value for each of the plurality of groups based on the second data group.
